(19) United States
(12) Patent Application Publication
(10) Pub. No.: US 2025/0215553 A1
(43) Pub. Date: Jul. 3, 2025

(54) SUBSTRATE PROCESSING METHOD, METHOD OF MANUFACTURING SEMICONDUCTOR DEVICE, NON-TRANSITORY COMPUTER-READABLE RECORDING MEDIUM AND SUBSTRATE PROCESSING APPARATUS

(71) Applicant: Kokusai Electric Corporation, Tokyo (JP)

(72) Inventor: Arito OGAWA, Toyama-shi (JP)

(73) Assignee: Kokusai Electric Corporation, Tokyo (JP)

(21) Appl. No.: 19/084,941

(22) Filed: Mar. 20, 2025

Related U.S. Application Data
(63) Continuation of application No. PCT/JP2023/011622, filed on Mar. 23, 2023.

(30) Foreign Application Priority Data
Sep. 21, 2022 (JP) 2022-149938

(51) Int. Cl. C23C 16/02

(52) U.S. Cl. CPC C23C 16/0227

(57) ABSTRACT

It is possible to improve a quality of a film formed on a substrate. There is provided a technique that includes: forming a film containing a first element on a substrate by performing a cycle a predetermined number of times, wherein the cycle includes: (a) supplying a source gas containing the first element and an organic ligand to the substrate; (b) supplying a treatment gas to the substrate to reduce an amount of by-products present on a surface of the substrate; and (c) supplying a first reactive gas to the substrate.

### CROSS-REFERENCE TO RELATED PATENT APPLICATION

This application is a bypass continuation application of PCT International Application No. PCT/JP2023/011622, filed on Mar. 23, 2023, in the WIPO, the international application being based upon and claiming the benefit of priority from Japanese Patent Application No. 2022-149938, filed on Sep. 21, 2022, in the Japanese Patent Office, the entire contents of which are hereby incorporated by reference.

### BACKGROUND

### 1. Field

The present disclosure relates to a substrate processing method, a method of manufacturing a semiconductor device, a non-transitory computer-readable recording medium and a substrate processing apparatus.

### 2. Related Art

According to some related arts, as a part of a manufacturing process of a semiconductor device, a process of forming a film on a substrate may be performed.

### SUMMARY

According to the present disclosure, there is provided a technique capable of improving a quality of a film formed on a substrate.

According to an embodiment of the present disclosure, there is provided a technique that includes: forming a film containing a first element on a substrate by performing a cycle a predetermined number of times, wherein the cycle includes: (a) supplying a source gas containing the first element and an organic ligand to the substrate; (b) supplying a treatment gas to the substrate to reduce an amount of by-products present on a surface of the substrate; and (c) supplying a first reactive gas to the substrate.

### BRIEF DESCRIPTION OF THE DRAWINGS

FIG. 1 is a diagram schematically illustrating a vertical cross-section of a vertical type process furnace of a substrate processing apparatus according to one or more embodiments of the present disclosure.

FIG. 2 is a diagram schematically illustrating a horizontal cross-section taken along a line A-A of the substrate processing apparatus shown in FIG. 1.

FIG. 3 is a block diagram schematically illustrating a configuration of a controller and related components of the substrate processing apparatus according to the embodiments of the present disclosure.

FIG. 4 is a flow chart schematically illustrating a flow of a substrate processing according to the embodiments of the present disclosure.

FIG. 5 is a diagram schematically illustrating a substrate processing sequence according to the embodiments of the present disclosure.

FIGS. 6A to 6F are diagrams schematically illustrating modified examples of the substrate processing sequence according to the embodiments of the present disclosure, respectively.

FIG. 7 is a diagram schematically illustrating another modified example of the substrate processing sequence according to the embodiments of the present disclosure.

### DETAILED DESCRIPTION

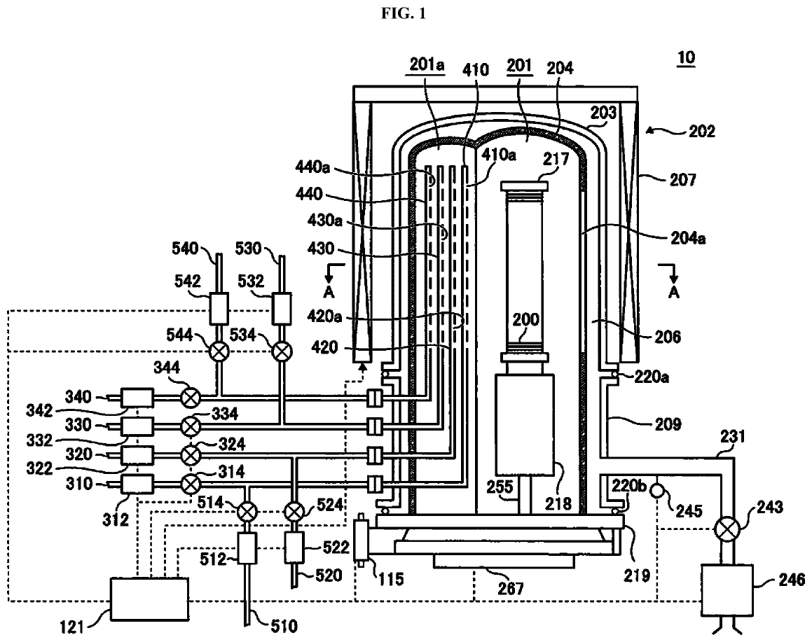

Hereinafter, one or more embodiments (hereinafter, also simply referred to as “embodiments”) according to the present disclosure will be described mainly with reference to FIGS. 1 to 5. For example, the drawings used in the following descriptions are all schematic, and a relationship between dimensions of each component and a ratio of each component shown in the drawing may not always match the actual ones. In addition, even between the drawings, the relationship between the dimensions of each component and the ratio of each component may not always match.

### (1) Configuration of Substrate Processing Apparatus

A substrate processing apparatus 10 according to the present embodiments includes a process furnace 202 provided with a heater 207 serving as a heating structure (which is a heating device or a heating system). The heater 207 is of a cylindrical shape, and is vertically installed while being supported by a heater base (not shown) serving as a support plate.

An outer tube 203 constituting a process vessel is provided in an inner side of the heater 207 to be aligned in a manner concentric with the heater 207. The outer tube 203 may also be referred to as an outer reaction tube (outer vessel). For example, the outer tube 203 is made of a heat resistant material such as quartz (SiO₂) and silicon carbide (SiC). The outer tube 203 is of a cylindrical shape with a closed upper end and an open lower end. A manifold (which is an inlet flange) 209 is provided under the outer tube 203 to be aligned in a manner concentric with the outer tube 203. For example, the manifold 209 is made of a metal such as stainless steel (SUS). The manifold 209 is of a cylindrical shape with open upper and lower ends. An O-ring 220a serving as a seal is provided between the upper end of the manifold 209 and the outer tube 203. As the manifold 209 is supported by the heater base (not shown), the outer tube 203 is installed vertically.

An inner tube 204 constituting the process vessel is provided in an inner side of the outer tube 203. The inner tube 204 may also be referred to as an inner reaction tube (inner vessel). For example, the inner tube 204 is made of a heat resistant material such as quartz (SiO₂) and silicon carbide (SiC). The inner tube 204 is of a cylindrical shape with a closed upper end and an open lower end. The process vessel is constituted mainly by the outer tube 203, the inner tube 204 and the manifold 209. A process chamber 201 is provided in a hollow cylindrical portion of the process vessel (that is, an inside of the inner tube 204).

The process chamber 201 is configured to be capable of accommodating a plurality of wafers including a wafer 200 serving as a substrate in a horizontal orientation to be vertically arranged in a multistage manner by a boat 217 described later. Hereinafter, the plurality of wafers including the wafer 200 may also be simply referred to as “wafers 200”.

Nozzles 410, 420, 430 and 440 are installed in the process chamber 201 so as to penetrate a side wall of the manifold 209 and the inner tube 204. Gas supply pipes 310, 320, 330 and 340 are connected to the nozzles 410, 420, 430 and 440, respectively. However, the process furnace 202 of the present embodiments is not limited to the example mentioned above.

Mass flow controllers (MFCs) 312, 322, 332 and 342 serving as flow rate controllers (flow rate control structures) and valves 314, 324, 334 and 344 serving as opening/closing valves are sequentially installed at the gas supply pipes 310, 320, 330 and 340 in this order from upstream sides to downstream sides of the gas supply pipes 310, 320, 330 and 340 in a gas flow direction, respectively. In addition, gas supply pipes 510, 520, 530 and 540 through which an inert gas is supplied are connected to the gas supply pipes 310, 320, 330 and 340 at downstream sides of the valves 314, 324, 334 and 344 in the gas flow direction, respectively. MFCs 512, 522, 532 and 542 and valves 514, 524, 534 and 544 are sequentially installed at the gas supply pipes 510, 520, 530 and 540 in this order from upstream sides to downstream sides of the gas supply pipes 510, 520, 530 and 540 in the gas flow direction, respectively.

The nozzles 410, 420, 430 and 440 are connected to front ends (tips) of the gas supply pipes 310, 320, 330 and 340, respectively. Each of the nozzles 410, 420, 430 and 440 may be configured as an L-shaped nozzle. Horizontal portions of the nozzles 410, 420, 430 and 440 are installed so as to penetrate the side wall of the manifold 209 and the inner tube 204. Vertical portions of the nozzles 410, 420, 430 and 440 are installed in a preliminary chamber 201a of a channel shape (a groove shape) protruding outward in a radial direction of the inner tube 204 and extending in the vertical direction. That is, the vertical portions of the nozzles 410, 420, 430 and 440 are installed in the preliminary chamber 201a to extend toward the upper end of the inner tube 204 (in a direction in which the wafers 200 are arranged) and along an inner wall of the inner tube 204.

The nozzles 410, 420, 430 and 440 extend from a lower region of the process chamber 201 to an upper region of the process chamber 201. The nozzles 410, 420, 430 and 440 are provided with a plurality of gas supply holes 410a, a plurality of gas supply holes 420a, a plurality of gas supply holes 430a and a plurality of gas supply holes 440a facing the wafers 200, respectively. Thereby, a gas such as a process gas can be supplied to the wafers 200 through the gas supply holes 410a of the nozzle 410, the gas supply holes 420a of the nozzle 420, the gas supply holes 430a of the nozzle 430 and the gas supply holes 440a of the nozzle 440. The gas supply holes 410a, the gas supply holes 420a, the gas supply holes 430a and the gas supply holes 440a are provided from a lower portion to an upper portion of the inner tube 204. An opening area of each of the gas supply holes 410a, the gas supply holes 420a, the gas supply holes 430a and the gas supply holes 440a is the same, and each of the gas supply holes 410a, the gas supply holes 420a, the gas supply holes 430a and the gas supply holes 440a is provided at the same pitch. However, the gas supply holes 410a, the gas supply holes 420a, the gas supply holes 430a and the gas supply holes 440a are not limited thereto. For example, the opening area of each of the gas supply holes 410a, the gas supply holes 420a, the gas supply holes 430a and the gas supply holes 440a may gradually increase from the lower portion to the upper portion of the inner tube 204 to further uniformize a flow rate of the gas supplied through the gas supply holes 410a, the gas supply holes 420a, the gas supply holes 430a and the gas supply holes 440a.

The gas supply holes 410a of the nozzle 410, the gas supply holes 420a of the nozzle 420, the gas supply holes 430a of the nozzle 430 and the gas supply holes 440a of the nozzle 440 are provided within a height range from a lower portion to an upper portion of the boat 217 described later. Therefore, the process gas supplied into the process chamber 201 through the gas supply holes 410a, the gas supply holes 420a, the gas supply holes 430a and the gas supply holes 440a is supplied onto the wafers 200 accommodated in the boat 217 from the lower portion to the upper portion thereof, that is, an entirety of the wafers 200 accommodated in the boat 217. It is preferable that the nozzles 410, 420, 430 and 440 extend from the lower region to the upper region of the process chamber 201. However, the nozzles 410, 420, 430 and 440 may preferably extend only to the vicinity of a ceiling of the boat 217.

A first process gas is supplied into the process chamber 201 through the gas supply pipe 310 provided with the MFC 312 and the valve 314 and the nozzle 410. In the embodiments of the present disclosure, the first process gas may also be referred to as a “modifying gas”, a “modifying agent”, an “adsorption inhibiting agent” or an “adsorption inhibiting gas”. In addition, the first process gas may also be referred to as a “first modifying agent” or a “first modifying gas”.

In the present specification, the term “agent” may contain at least one selected from the group of a gaseous substance and a liquid substance. The liquid substance may contain a mist substance. That is, each of the modifying agent and the adsorption inhibiting agent may contain a gaseous substance, may contain a liquid substance such as a mist substance, or may contain both of the gaseous substance and the liquid substance.

A second process gas is supplied into the process chamber 201 through the gas supply pipe 320 provided with the MFC 322 and the valve 324 and the nozzle 420. In the embodiments of the present disclosure, the second process gas may also be referred to as a “source gas, a “gas containing a first element”, a “gas containing a first element and a ligand” or a “gas containing a first element and an organic ligand”.

A third process gas is supplied into the process chamber 201 through the gas supply pipe 330 provided with the MFC 332 and the valve 334 and the nozzle 430. In the embodiments of the present disclosure, the third process gas is used as a reactive gas reacting with the source gas. In the embodiments of the present disclosure, the third process gas may also be referred to as a “treatment gas”, a “second modifying agent”, a “second modifying gas”, or a “reducing gas (first reducing gas)”. In the embodiments of the present disclosure, the treatment gas may also be referred to as a “second reactive gas”.

A fourth process gas is supplied into the process chamber 201 through the gas supply pipe 340 provided with the MFC 342 and the valve 344 and the nozzle 440. In the embodiments of the present disclosure, the fourth process gas may also be referred to as a “reactant” serving as a first reactive gas, a “reactive gas”, a “gas containing a second element (second element-containing gas)”, a “third modifying agent” or a “third modifying gas”.

The inert gas is supplied into the process chamber 201 through the gas supply pipes 510, 520, 530 and 540 provided with the MFCs 512, 522, 532 and 542 and the valves 514, 524, 534 and 544, respectively, and the nozzles 410, 420, 430 and 440.

A process gas supplier (which is a process gas supply structure or a process gas supply system) is constituted mainly by the gas supply pipes 310, 320, 330 and 340, the MFCs 312, 322, 332 and 342, the valves 314, 324, 334 and 344, and the nozzles 410, 420, 430 and 440. However, the process gas supplier may be constituted by the nozzles 410, 420, 430 and 440 without including other components mentioned above. The process gas supplier may also be simply referred to as a “gas supplier” which is a gas supply structure or a gas supply system. When the first process is supplied through the gas supply pipe 310, a first process gas supplier (which is a first process gas supply structure or a first process gas supply system) is constituted mainly by the gas supply pipe 310, the MFC 312 and the valve 314. The first process gas supplier may further include the nozzle 410. The first process gas supplier may also be referred to as a “modifying agent supplier” which is a modifying agent supply structure or a modifying agent supply system. In addition, when the second process gas is supplied through the gas supply pipe 320, a second process gas supplier (which is a second process gas supply structure or a second process gas supply system) is constituted mainly by the gas supply pipe 320, the MFC 322 and the valve 324. The second process gas supplier may further include the nozzle 420. The second process gas supplier may also be referred to as a “source gas supplier” which is a source gas supply structure or a source gas supply system. In addition, when the third process gas is supplied through the gas supply pipe 330, a third process gas supplier (which is a third process gas supply structure or a third process gas supply system) is constituted mainly by the gas supply pipe 330, the MFC 332 and the valve 334. The third process gas supplier may further include the nozzle 430. The third process gas supplier may also be referred to as a “treatment gas supplier” which is a treatment gas supply structure or a treatment gas supply system, or as a “second reactive gas supplier” which is a second reactive gas supply structure or a second reactive gas supply system. In addition, when the fourth process gas is supplied through the gas supply pipe 340, a fourth process gas supplier (which is a fourth process gas supply structure or a fourth process gas supply system) is constituted mainly by the gas supply pipe 340, the MFC 342 and the valve 344. The fourth process gas supplier may further include the nozzle 440. The fourth process gas supplier may also be referred to as a “reactant supplier” which is a reactant supply structure or a reactant supply system, or as a “first reactive gas supplier” which is a first reactive gas supply structure or a first reactive gas supply system. In addition, an inert gas supplier (which is an inert gas supply structure or an inert gas supply system) is constituted mainly by the gas supply pipes 510, 520, 530 and 540, the MFCs 512, 522, 532 and 542 and the valves 514, 524, 534 and 544.

According to the present embodiments, the gas is supplied into a vertically long annular space (which is defined by the inner wall of the inner tube 204 and edges (peripheries) of the wafers 200) through the nozzles 410, 420, 430 and 440 provided in the preliminary chamber 201a. Then, the gas is ejected into the inner tube 204 through the gas supply holes 410a of the nozzle 410, the gas supply holes 420a of the nozzle 420, the gas supply holes 430a of the nozzle 430 or the gas supply holes 440a of the nozzle 440 provided at the positions facing the wafers 200. More specifically, gases such as the first process gas, the second process gas, the third process gas and the fourth process gas are ejected into the inner tube 204 in a direction parallel to surfaces of the wafers 200 through the gas supply holes 410a of the nozzle 410, the gas supply holes 420a of the nozzle 420, the gas supply holes 430a of the nozzle 430 and the gas supply holes 440a of the nozzle 440.

An exhaust hole (which is an exhaust port) 204a is a through-hole facing the nozzles 410, 420, 430 and 440, and is provided at a side wall of the inner tube 204. For example, the exhaust hole 204a may be of a narrow slit-shaped through-hole elongating vertically. The gas supplied into the process chamber 201 through the gas supply holes 410a of the nozzle 410, the gas supply holes 420a of the nozzle 420, the gas supply holes 430a of the nozzle 430 or the gas supply holes 440a of the nozzle 440 flows over the surfaces of the wafers 200. The gas that has flowed over the surfaces of the wafers 200 is exhausted through the exhaust hole 204a into a gap (that is, an exhaust path 206) provided between the inner tube 204 and the outer tube 203. The gas flowing in the exhaust path 206 flows into an exhaust pipe 231 and is then discharged (exhausted) out of the process furnace 202.

The exhaust hole 204a is provided to face the wafers 200. The gas supplied to the vicinity of the wafers 200 in the process chamber 201 through the gas supply holes 410a, the gas supply holes 420a, the gas supply holes 430a or the gas supply holes 440a flows in the horizontal direction. The gas that has flowed in the horizontal direction is exhausted through the exhaust hole 204a into the exhaust path 206. The exhaust hole 204a is not limited to the slit-shaped through-hole. For example, the exhaust hole 204a may be configured as a plurality of holes.

The exhaust pipe 231 through which an atmosphere (inner atmosphere) of the process chamber 201 is exhausted is installed at the manifold 209. A pressure sensor 245 serving as a pressure detector (pressure detecting structure) configured to detect a pressure (inner pressure) of the process chamber 201, an APC (Automatic Pressure Controller) valve 243 and a vacuum pump 246 serving as a vacuum exhaust apparatus are sequentially connected to the exhaust pipe 231 in this order from an upstream side to a downstream side of the exhaust pipe 231 in the gas flow direction. With the vacuum pump 246 in operation, the APC valve 243 may be opened or closed to perform a vacuum exhaust of the process chamber 201 or stop the vacuum exhaust. In addition, with the vacuum pump 246 in operation, an opening degree of the APC valve 243 may be adjusted in order to adjust the inner pressure of the process chamber 201. An exhauster (which is an exhaust structure or an exhaust system) is constituted mainly by the exhaust hole 204a, the exhaust path 206, the exhaust pipe 231, the APC valve 243 and the pressure sensor 245. The exhauster may further include the vacuum pump 246.

A seal cap 219 serving as a furnace opening lid capable of airtightly sealing (closing) a lower end opening of the manifold 209 is provided under the manifold 209. The seal cap 219 is in contact with the lower end of the manifold 209 from thereunder. For example, the seal cap 219 is made of a metal such as SUS, and is of a disk shape. An O-ring 220b serving as a seal is provided on an upper surface of the seal cap 219 so as to be in contact with the lower end of the manifold 209. A rotator (which is a rotating structure) 267 configured to rotate the boat 217 accommodating the wafers 200 is provided at the seal cap 219 in a manner opposite to the process chamber 201. A rotating shaft 255 of the rotator 267 is connected to the boat 217 through the seal cap 219. As the rotator 267 rotates the boat 217, the wafers 200 are rotated. The seal cap 219 may be elevated or lowered in the vertical direction by a boat elevator 115 serving as an elevating structure vertically provided outside the outer tube 203. When the seal cap 219 is elevated or lowered in the vertical direction by the boat elevator 115, the boat 217 may be transferred (loaded) into the process chamber 201 or transferred (unloaded) out of the process chamber 201. The boat elevator 115 serves as a transfer device (which is a transfer structure or a transfer system) that loads the boat 217 and the wafers 200 accommodated in the boat 217 into the process chamber 201 or that unloads the boat 217 and the wafers 200 accommodated in the boat 217 out of the process chamber 201.

The boat 217 serving as a substrate support (substrate retainer) is configured to accommodate (or support) the wafers 200 (for example, 25 to 200 wafers) while the wafers 200 are horizontally oriented with their centers aligned with one another with a predetermined interval therebetween in the vertical direction. For example, the boat 217 is made of a heat resistant material such as quartz and SiC. A plurality of heat insulating plates 218 horizontally oriented are placed under the boat 217 in a multistage manner (not shown). For example, each of the heat insulating plates 218 is made of a heat resistant material such as quartz and SiC. With such a configuration, the heat insulating plates 218 suppress the transmission of the heat from the heater 207 to the seal cap 219. However, the present embodiments are not limited thereto. For example, instead of the heat insulating plates 218, a heat insulating cylinder (not shown) such as a cylinder made of a heat resistant material such as quartz and SiC may be provided under the boat 217.

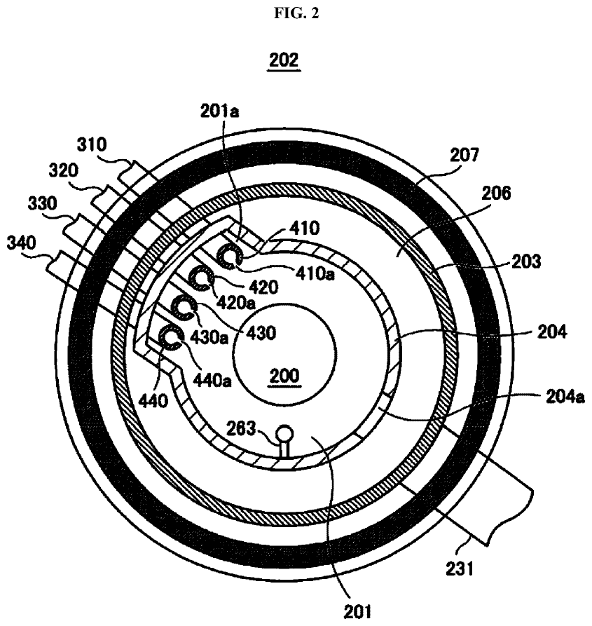

As shown in FIG. 2, a temperature sensor 263 serving as a temperature detector is installed in the inner tube 204. An amount of the electric current supplied (or applied) to the heater 207 is adjusted based on temperature information detected by the temperature sensor 263 such that a desired temperature distribution of a temperature (inner temperature) of the process chamber 201 can be obtained. Similar to the nozzles 410, 420, 430 and 440, the temperature sensor 263 is L-shaped, and is provided along the inner wall of the inner tube 204.

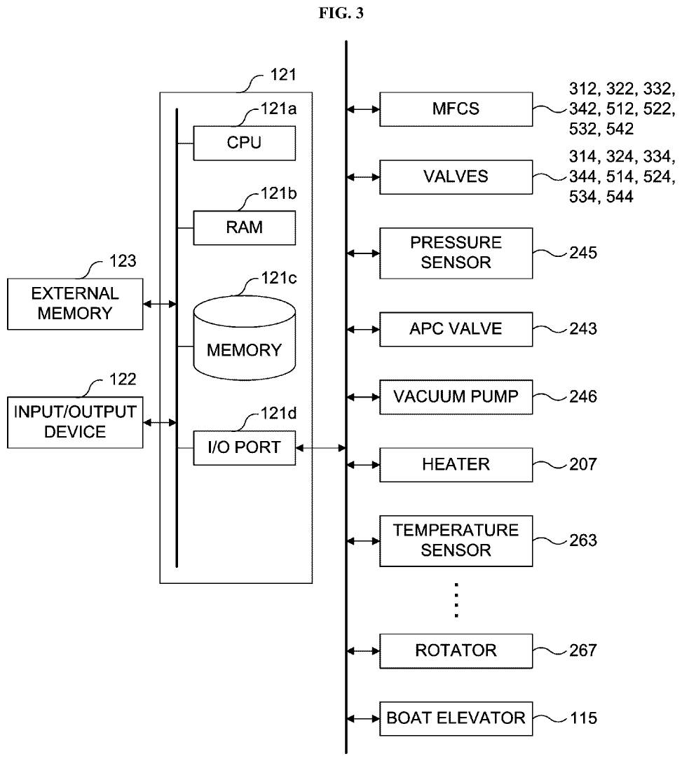

As shown in FIG. 3, a controller 121 serving as a control device (or a control structure) is constituted by a computer including a CPU (Central Processing Unit) 121a, a RAM (Random Access Memory) 121b, a memory 121c and an I/O port 121d. The RAM 121b, the memory 121c and the I/O port 121d may exchange data with the CPU 121a through an internal bus (not shown). For example, an input/output device 122 constituted by a component such as a touch panel is connected to the controller 121. For example, as the controller 121, the substrate processing apparatus may include a single control structure, or include a plurality of control structures. That is, a control operation of performing a process sequence (substrate processing sequence) described later may be performed using the single control structure, or may be performed using the plurality of control structures. In addition, the plurality of control structures may be configured as a control system connected to one another via a wired or wireless communication network, and an entirety of the control system may perform the control operation of performing the process sequence described below. Thus, in the present specification, the term “controller 121” may refer to the single control structure, may refer to each of the plurality of control structures, or may refer to the control system configured by the plurality of control structures.

The memory 121c is configured by a component such as a flash memory and a hard disk drive (HDD). For example, a control program configured to control an operation of the substrate processing apparatus 10 or a process recipe containing information on procedures and conditions of a method of manufacturing a semiconductor device described later is readably stored in the memory 121c. The process recipe is obtained by combining steps (procedures) of the method of manufacturing the semiconductor device described later such that the controller 121 can execute the steps to acquire a predetermined result, and functions as a program. Hereafter, the process recipe and the control program may be collectively or individually referred to as a “program”. Thus, in the present specification, the term “program” may refer to the process recipe alone, may refer to the control program alone, or may refer to a combination of the process recipe and the control program. The RAM 121b functions as a memory area (work area) where a program or data read by the CPU 121a is temporarily stored.

The I/O port 121d is connected to the components described above such as the MFCs 312, 322, 332, 342, 512, 522, 532 and 542, the valves 314, 324, 334, 344, 514, 524, 534 and 544, the pressure sensor 245, the APC valve 243, the vacuum pump 246, the heater 207, the temperature sensor 263, the rotator 267 and the boat elevator 115.

The CPU 121a is configured to read the control program from the memory 121c and execute the read control program. In addition, the CPU 121a is configured to read a recipe such as the process recipe from the memory 121c in accordance with an operation command inputted from the input/output device 122. In accordance with the contents of the read recipe, the CPU 121a may be configured to control various operations such as flow rate adjusting operations for various gases by the MFCs 312, 322, 332, 342, 512, 522, 532 and 542, opening and closing operations of the valves 314, 324, 334, 344, 514, 524, 534 and 544, an opening and closing operation of the APC valve 243, a pressure adjusting operation by the APC valve 243 based on the pressure sensor 245, a temperature adjusting operation by the heater 207 based on the temperature sensor 263, a start and stop of the vacuum pump 246, an operation of adjusting a rotation and a rotation speed of the boat 217 by the rotator 267, an elevating and lowering operation of the boat 217 by the boat elevator 115 and an operation of transferring and accommodating the wafer 200 into the boat 217.

The controller 121 may be embodied by installing the above-mentioned program stored in an external memory 123 into the computer. For example, the external memory 123 may include a magnetic tape, a magnetic disk such as a flexible disk and a hard disk, an optical disk such as a CD and a DVD, a magneto-optical disk such as an MO and a semiconductor memory such as a USB memory and a memory card. The memory 121c or the external memory 123 may be embodied by a non-transitory computer readable recording medium. Hereafter, the memory 121c and the external memory 123 may be collectively or individually referred to as a “recording medium”. Thus, in the present specification, the term “recording medium” may refer to the memory 121c alone, may refer to the external memory 123 alone, and may refer to both of the memory 121c and the external memory 123. Instead of the external memory 123, a communication structure such as the Internet and a dedicated line may be used for providing the program to the computer.

### (2) Substrate Processing

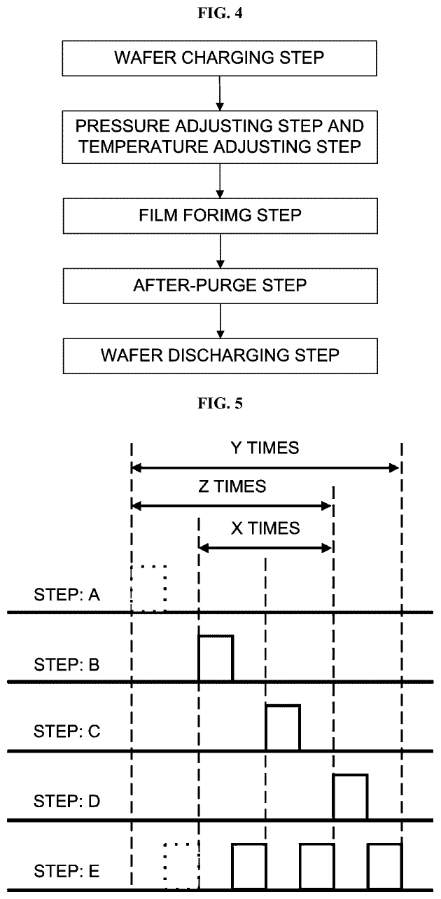

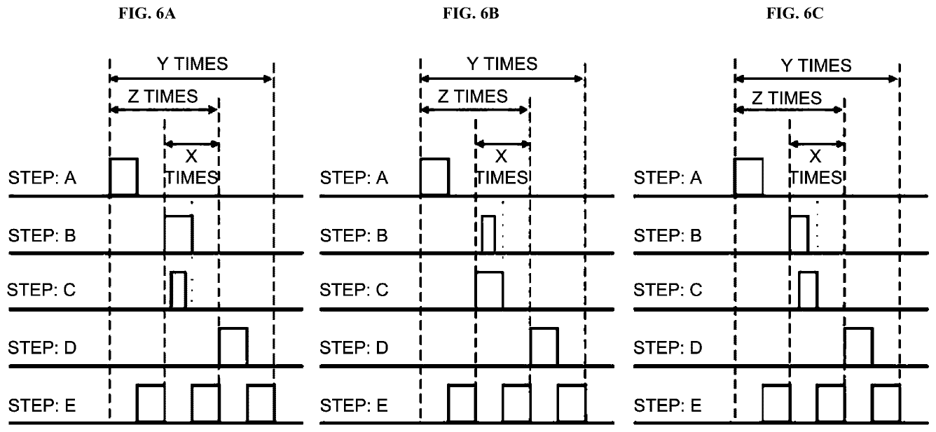

Hereinafter, an exemplary step of a film forming process of forming a film (first-element containing film) containing the first element on the wafer 200, which is performed as a part of a manufacturing process of the semiconductor device, will be described with reference to FIGS. 4 and 5. The exemplary step of forming the film is performed using the process furnace 202 of the substrate processing apparatus 10 mentioned above. In the following description, operations of components constituting the substrate processing apparatus 10 are controlled by the controller 121.

A substrate processing (that is, the manufacturing process of the semiconductor device) according to the embodiments of the present disclosure may include:
forming the film containing the first element on the wafer 200 by performing a cycle a predetermined number of times, wherein the cycle comprises:
   (a) supplying the source gas containing the first element and the organic ligand to the wafer 200;
   (b) supplying the treatment gas to the wafer 200 to reduce an amount of by-products present on the surface of the wafer 200; and
   (c) supplying a reactant to the wafer 200.

In the present specification, the term “wafer” may refer to “a wafer itself”, or may refer to “a wafer and a stacked structure (aggregated structure) of a predetermined layer (or layers) or a film (or films) formed on a surface of the wafer”. In the present specification, the term “a surface of a wafer” may refer to “a surface of a wafer itself”, or may refer to “a surface of a predetermined layer (or a predetermined film) formed on a wafer”. Thus, in the present specification, “forming a predetermined layer (or a film) on a wafer” may refer to “forming a predetermined layer (or a film) directly on a surface of a wafer itself”', or may refer to “forming a predetermined layer (or a film) on a surface of another layer (or another film) formed on a wafer”. In the present specification, the terms “substrate” and “wafer” may be used as substantially the same meaning.

### <Wafer Charging Step and Boat Loading Step>

The wafers 200 are charged (transferred) into the boat 217 (wafer charging step). After the boat 217 is charged with the wafers 200, as shown in FIG. 1, the boat 217 supporting the wafers 200 is elevated by the boat elevator 115 and loaded (transferred) into the process chamber 201 of the process vessel (boat loading step), and accommodated in the process vessel. With the boat 217 accommodated in the process vessel, the seal cap 219 seals a lower end opening of the outer tube 203 via the O-ring 220b.

### <Pressure Adjusting Step and Temperature Adjusting Step>

Then, the vacuum pump 246 vacuum-exhausts (decompresses and exhausts) the inner atmosphere of the process chamber 201 (that is, a space in which the wafers 200 are present (accommodated)) such that the inner pressure of the process chamber 201 reaches and is maintained at a desired pressure (vacuum degree). When the vacuum pump 246 vacuum-exhausts the inner atmosphere of the process chamber 201, the inner pressure of the process chamber 201 is measured by the pressure sensor 245, and the APC valve 243 is feedback-controlled based on the pressure information detected by the pressure sensor 245 (pressure adjusting step). The vacuum pump 246 continuously vacuum-exhausts the inner atmosphere of the process chamber 201 until at least a processing of the wafer 200 is completed. In addition, the heater 207 heats the process chamber 201 such that the inner temperature of the process chamber 201 reaches and is maintained at a desired process temperature. When the heater 207 heats the process chamber 201, an amount of the electric current supplied to the heater 207 is feedback-controlled based on the temperature information detected by the temperature sensor 263 such that the desired temperature distribution of the inner temperature of the process chamber 201 can be obtained (temperature adjusting step). The heater 207 continuously heats the process chamber 201 until at least the processing of the wafer 200 is completed.

### <STEP A: Modifying Agent Supply Step>

As shown by a dashed box in FIG. 5, a step A may be performed. In the step A, the valve 314 is opened to supply the modifying agent into the gas supply pipe 310. After a flow rate of the modifying agent is adjusted by the MFC 312, the modifying agent whose flow rate is adjusted is supplied into the process chamber 201 through the gas supply holes 410a of the nozzle 410, and is exhausted through the exhaust pipe 231. Thereby, the modifying agent is supplied onto the wafer 200 (modifying agent supply step). The modifying agent may be supplied in a diluted state, that is, diluted with a dilution gas such as the inert gas.

By supplying the modifying agent to the wafer 200 in accordance with process conditions described below, the modifying agent is physically adsorbed on the surface of the wafer 200. Thereby, it is possible to form, on the wafer 200, an adsorption layer containing the modifying agent physically adsorbed to the surface of the wafer 200. As a result of forming the adsorption layer, some of adsorption sites present (existing) on the surface of the wafer 200 are covered by the adsorption layer, and some other adsorption sites are not covered by the adsorption layer and thereby exposed. In the present specification, for example, the adsorption sites present on the surface of the wafer 200 may contain a hydroxy group (OH group) that terminates the surface of the wafer 200. In addition, since the modifying agent contains an organic compound as described below, at least a portion of the surface of the adsorption layer may be terminated with a substance such as a hydrocarbon group.

It is preferable that a thickness of the adsorption layer is set to be less than one molecular layer. That is, it is preferable that the adsorption layer contains the modifying agent adsorbed so as to cover the surface of the wafer 200 discontinuously. As a result, it is possible to reliably expose some of the adsorption sites (OH groups) present on the surface of the wafer 200. However, at the present stage, the modifying agent may be physically adsorbed on the surface of the wafer 200 such that the thickness of the adsorption layer is set to be one molecular layer or more (that is, the surface of the wafer 200 is covered with a continuous layer), and the adsorption layer whose thickness is less than one molecular layer may be formed by removing a part of the modifying agent contained in the adsorption layer from the surface of the wafer 200.

For example, in the present step, the adsorption layer is formed on at least a surface adjacent to an opening (particularly on a side wall adjacent to the opening) of an inner surface of a concave structure (recess) formed on the surface of the wafer 200. In addition, as will be described later, in the present step, it is more preferable that the adsorption layer is formed on a bottom surface and side walls of the inner surface of the concave structure.

After the adsorption layer is formed on the wafer 200, the valve 314 is closed to stop a supply of the modifying agent into the process chamber 201.

After the supply of the modifying agent to the wafer 200 is completed (stopped), as shown by a dashed box in FIG. 5, a step E may be performed. In the step E, with the supply of the modifying agent into the process chamber 201 stopped, the inner atmosphere of the process chamber 201 is exhausted to remove a substance such as the gas remaining in the process chamber 201 from the process chamber 201.

In addition, as shown in FIG. 5, in the step E, it is preferable that the valves 514 to 544 are opened to supply the inert gas into the process chamber 201 through the nozzles 410 to 440. That is, in the step E, it is preferable to exhaust the inner atmosphere of the process chamber 201 while supplying the inert gas to the wafer 200. In addition, preferably, a step of exhausting the inner atmosphere of the process chamber 201 while supplying the inert gas to the wafer 200 and a step of exhausting the inner atmosphere of the process chamber 201 while a supply of the inert gas is stopped may be performed. In addition, preferably, in the step E, a purge cycle (which includes the step of exhausting the inner atmosphere of the process chamber 201 while supplying the inert gas to the wafer 200 and the step of exhausting the inner atmosphere of the process chamber 201 while the supply of the inert gas is stopped) may be performed a plurality number of times. In the purge cycle, the step of exhausting the inner atmosphere of the process chamber 201 while supplying the inert gas to the wafer 200 and the step of exhausting the inner atmosphere of the process chamber 201 while the supply of the inert gas is stopped are performed non-simultaneously. The same may also apply to the following description.

For example, the process conditions in the step A (modifying agent supply step) are as follows:
A supply flow rate of the modifying agent (excluding the dilution gas): from 0.01 g/minute to 10 g/minute, more preferably from 0.1 g/minute to 5 g/minute;
A supply flow rate of the dilution gas: from 100 sccm to 100,000 sccm, more preferably from 1,000 sccm to 50,000 sccm;
A supply time (time duration) of supplying the modifying agent: from 1 second to 600 seconds, more preferably from 10 seconds to 300 seconds;
A supply flow rate of the inert gas (for each gas supply pipe): from 0 sccm to 50,000 sccm, more preferably from 5,000 sccm to 15,000 sccm;
A process temperature: from 200°° C. to 500° C., more preferably from 200° C. to 350° C.; and
A process pressure: from 100 Pa to 10,000 Pa, more preferably from 100 Pa to 1,000 Pa.

In addition, in the present specification, a notation of a numerical range such as “from 100sccm to 100,000 sccm” means that a lower limit and an upper limit are included in the numerical range. Therefore, for example, a numerical range “from 100 sccm to 100,000 sccm” means a range equal to or higher than 100 sccm and equal to or less than 100,000 sccm. The same also applies to other numerical ranges described in the present specification. In addition, when a supply flow rate of a substance is zero (0) sccm, it refers to a case where the substance is not supplied.

In the present specification, the term “process temperature” may refer to the temperature of the wafer 200 or may refer to the inner temperature of the process chamber 201, and the term “process pressure” may refer to the inner pressure of the process chamber 201. The same also applies to the following description.

As the modifying agent, a gas containing an organic compound may be used. As the gas containing the organic compound, for example, a gas containing at least one selected from the group of an ether compound, a ketone compound, an amine compound, an organic hydrazine compound and the like may be used. As a gas containing the ether compound, a gas containing at least one selected from the group of dimethyl ether, diethyl ether, methyl ethyl ether, propyl ether, isopropyl ether, furan, tetrahydrofuran, pyran, tetrahydropyran and the like may be used. As a gas containing a ketone compound, a gas containing at least one selected from the group of dimethyl ketone, diethyl ketone, methyl ethyl ketone, methyl propyl ketone and the like may be used. As a gas containing the amine compound, a gas containing at least one selected from the group of a methylamine compound (such as monomethylamine, dimethylamine and trimethylamine), an ethylamine compound (such as monoethylamine, diethylamine and triethylamine), a methylethylamine compound (such as dimethylethylamine and methyldiethylamine) and the like may be used. As a gas containing the organic hydrazine compound, a gas containing at least one selected from methylhydrazine-based gases (such as monomethylhydrazine, dimethylhydrazine and trimethylhydrazine) may be used. As the modifying agent, one or more of the substances exemplified above may be used. In addition, as the modifying agent, it is preferable to use a gas that is difficult to be chemically adsorbed onto the surface of the wafer 200. In order to form the adsorption layer containing the modifying agent physically adsorbed on the surface of the wafer 200, for example, a gas that is substantially chemically unreactive with the adsorption sites (OH groups) on the surface of the wafer 200 may be preferably used.

As the inert gas, for example, nitrogen (N₂) gas or a rare gas such as argon (Ar) gas, helium (He) gas, neon (Ne) gas and xenon (Xe) gas may be used. As the inert gas, one or more of the substances exemplified above may be used. The same also applies to each step described below.

### <Step B: Source Gas Supply Step>

After the step A is completed, the source gas is supplied onto the wafer 200 in the process chamber 201, that is, onto the wafer 200 where the adsorption layer is formed on the surface thereof.

Specifically, the valve 324 is opened to supply the source gas into the gas supply pipe 320. After a flow rate of the source gas is adjusted by the MFC 322, the source gas whose flow rate is adjusted is supplied into the process chamber 201 through the nozzle 420, and is exhausted through the exhaust hole 204a. Thereby, the source gas is supplied onto the wafer 200 (source gas supply step). The source gas may be supplied in a diluted state, that is, diluted with the dilution gas such as the inert gas. In addition, in the present step, the valves 514 to 544 may be opened to supply the inert gas into the process chamber 201 through each of the nozzles 410 to 440.

By supplying the source gas to the wafer 200 in accordance with process conditions described below, it is possible to react the source gas with the surface of the wafer 200. As described later, the source gas contains a molecule (hereinafter, also referred to as a “source molecule”) containing the first element and the ligand bonded to the first element. When the source gas reaches the surface of the wafer 200, the source gas reacts with an exposed surface (which is not covered by a modified layer) of the wafer 200, that is, the adsorption sites (OH groups) exposed on the surface of the wafer 200. In a process of such a reaction, the ligand is desorbed from the first element (which is a primary element or a main element) contained in the source gas, and the first element (which contains unbonded species due to a desorption of the ligand) is chemically adsorbed (bonded) to the surface of the wafer 200. As the reaction described above progresses, a first layer containing the first element is formed on the wafer 200, that is, on the exposed surface (exposed portion) of the wafer 200, which is not covered by the adsorption layer.

In addition, when forming the first layer, a predetermined first by-product may be generated. The first by-product may contain the ligand (also referred to as a “single ligand”) desorbed from the first element due to a reaction between the source gas and the adsorption sites exposed on the surface of the wafer 200. In addition, for example, the first by-product may contain a molecule in which a part of the ligand is desorbed from the source molecule containing the first element and the ligand bonded to the first element. In addition, for example, the molecule in which the part of the ligand is desorbed from the source molecule containing the first element and the ligand bonded to the first element may be generated by a thermal decomposition of the source gas supplied into the process chamber 201.

As described later, the first by-product may contain the organic ligand (organic substance). Further, it is not preferable for the first by-product to be adsorbed (adhered) to a surface of the film formed on the wafer 200 or to remain in the film. When the first by-product is adsorbed to the surface of the film or when the first by-product remains in the film, the thickness of the film may increase. Therefore, when an amount of the adsorption of the first by-product or a residual amount of the first by-product is non-uniform within the surface of the wafer 200 or within the inner surface (inner wall) of the concave structure on the wafer 200, a thickness uniformity of the film (which is formed on the wafer 200) within the surface of the wafer 200 and/or a step coverage of the film (which is formed within the inner surface of the concave structure) may deteriorate. Further, when the first by-product remains in the film, since impurities derived from the first by-product in the film may increase, it may decrease a quality of the film. For example, an increase in the thickness of the film is considered to occur as follows. When the first by-product (ligand) present on the wafer 200 after the first layer is formed reacts with the reactant (reactive gas), a second by-product is generated. When the second by-product remains on the wafer 200, the second by-product reacts with the source gas in the source gas supply step of a subsequent execution of the cycle to form an unintended layer (film). As a result, the increase in the thickness of the film may occur. The second by-product may contain hydrogen (H) and oxygen (O). As the second by-product, one or more substances represented by a formula R1ₓ—O—R2_{y} may be generated (formed). In the present embodiments, each of R1 and R2 may contain at least one selected from the group of hydrogen, nitrogen (N), halogen and the organic ligand, and each of x and y is an integer equal to or greater than 0. For example, the organic ligand may include a substance such as a C1 to C5 alkyl group and an amine group. As such a second by-product, for example, a substance such as H2O, an OH-group, an O(oxygen)-group, an amide, an ester, an aldehyde, a carboxylic acid and a ketone may be generated. For example, the formula mentioned above may include an ether compound, but as mentioned above, may also include a substance other than the ether compound. For example, the substance other than the ether compound may include a substance such as H₂O and an OH-group. Such a second by-product may be generated by a reaction between a hydrocarbon group serving as the ligand (particularly, the organic ligand) contained in the source gas and an oxygen-containing gas serving as the reactant. The second by-product is likely to be generated when the source gas contains, as the organic ligand, at least one among the hydrocarbon group and an amino group. In addition, the second by-product is likely to be generated when the source gas contains both of the hydrocarbon group and the amino group. In addition, the second by-product is likely to be generated when the source gas contains an alkylamino group. Since the second by-product is generated by the reaction between at least one among the hydrocarbon group and the amino group and the reactant, when the modifying agent containing at least one among the hydrocarbon group and the amino group is used, the modifying agent present on the wafer 200 after the source gas is supplied may react with the reactant to generate the second by-product. For example, when the H₂O is generated as the second by-product, the H₂O is difficult to be removed from the wafer 200 by a method such as a purge, and when a cyclic process is performed (that is, the cycle mentioned above is performed) a plurality number of times to form the film, the H₂O may remain until the subsequent execution of the cycle is performed. Thus, an unintended reaction may occur between the H₂O present on the wafer 200 and the source gas supplied in the subsequent execution of the cycle. Further, when the modifying agent is used to form the film, such a second by-product may react unintendedly with the modifying agent. Thereby, it is difficult to obtain an effect of the modifying agent.

In order to solve such problems described above, according to the present embodiments, an amount of the first by-product generated when the first layer is being formed is reduced in a step C described later. Thereby, it is possible to suppress a generation of the second by-product generated by a reaction between the first by-product and the reactant. As a result, it is possible to suppress an uncontrolled and non-uniform increase in the thickness of the film formed on the wafer 200, which is caused by a reaction between the second by-product and the source gas supplied in the subsequent execution of the cycle.

After a process of forming the first layer on the wafer 200 is completed, the valve 324 is closed to stop a supply of the source gas into the process chamber 201.

After the supply of the source gas to the wafer 200 is completed (stopped), as shown in FIG. 5, preferably, the step E is performed. In the step E, with the supply of the source gas into the process chamber 201 stopped, the inner atmosphere of the process chamber 201 is exhausted to remove the substance such as the gas remaining in the process chamber 201 from the process chamber 201.

By performing the step E, it is possible to remove an atmosphere containing the substance remaining in the process chamber 201 (such as the source gas which did not react or which did contribute to a formation of the first layer, and the first by-product) from the process chamber 201.

In addition, by performing the step E, it is possible to desorb the modifying agent contained in the adsorption layer (that is, the modifying agent physically adsorbed to the surface of the wafer 200) from the surface of the wafer 200. As a result, it is possible to prevent (suppress) the modifying agent from remaining in the film formed on the wafer 200. Thereby, it is possible to form the film whose concentration of the impurities caused by the modifying agent is low.

Further, by performing the step E, it is possible to remove the first by-product adhered to the adsorption layer from the surface of the wafer 200 together with the modifying agent contained in the adsorption layer (that is, the modifying agent physically adsorbed to the surface of the wafer 200). As a result, it is possible to prevent (suppress) the first by-product from remaining in the film formed on the wafer 200. Further, it is also possible to form the film whose step coverage and/or thickness uniformity is desirable within the surface of the wafer 200 and whose concentration of the impurities caused by the first by-product is low.

By performing the step E in accordance with one of the examples described above, it is possible to more efficiently remove a part of the modifying agent physically adsorbed on the surface of the wafer 200 from the surface of the wafer 200, and it is also possible to more reliably obtain the effects described above.

For example, the process conditions in the step B (source gas supply step) are as follows:
A supply flow rate of the source gas (excluding the dilution gas): from 0.1 g/minute to 10 g/minute, more preferably from 0.5 g/minute to 5 g/minute;
A supply flow rate of the dilution gas: from 100 sccm to 100,000 sccm, more preferably from 1,000 sccm to 50,000 sccm;
A supply time (time duration) of supplying the source gas: from 10 seconds to 600 seconds, more preferably from 30 seconds to 300 seconds; and
A supply flow rate of the inert gas (for each gas supply pipe): from 0 sccm to 50,000 sccm, more preferably from 5,000 sccm to 15,000 sccm.

The other process conditions of the present step may be set to be substantially the same as those of the step A of supplying the modifying agent.

The process conditions in the step E after the step B may be the same (substantially the same) as the process conditions in the step E after the step A.

As the source gas, a gas containing the molecule (source molecule) containing the first element and the ligand bonded to the first element may be used. As the first element, for example, a metal element, preferably a transition metal element, and more preferably a Group 4 element such as zirconium (Zr), hafnium (Hf) and titanium (Ti) may be used. In addition, as the first element, for example, a Group 13 element such as aluminum (Al), gallium (Ga) and indium (In) may be used. In addition, as the first element, for example, a Group 14 element such as silicon (Si) and germanium (Ge) may be used. As the ligand bonded to the first element, for example, the organic ligand, preferably a hydrocarbon group containing at least one selected from the group of an alkyl group (such as a methyl group, an ethyl group, a propyl group and a butyl group), a cyclopentadienyl group, a cyclohexadienyl group, a cycloheptatrienyl group and the like may be used. In addition, as the ligand bonded to the first element, for example, a substance such as the amino group and the alkylamino group may be used.

As the source containing zirconium (Zr) as the first element, for example, a gas containing at least one selected from the group of tetrakis (ethylmethylamino) zirconium (Zr[N(CH₃)C₂H₅]₄), tetrakis (diethylamino) zirconium (Zr[N(C₂H₅)₂]₄), tetrakis (dimethylamino) zirconium (Zr[N(CH₃)₂]₄), Zr(MMP)₄, Zr (O-tBu)₄, tris (dimethylaminocyclopentadienyl) zirconium ((C₅H₅)Zr[N(CH₃)₂]₃), ZrCp[N(CH₃)₂]₃ and the like may be used. As the source gas, one or more of the substances exemplified above may be used.

As the source gas containing hafnium (Hf) as the first element, for example, a gas containing at least one selected from the group of tetrakis (ethylmethylamino) hafnium (Hf[N(CH₃)C₂H₅]₄), tetrakis (diethylamino) hafnium (Hf[N(C₂H₅)₂]₄), tetrakis (dimethylamino) hafnium (Hf[N(CH₃)₂]₄), Hf(O-tBu)₄, Hf(MMP)₄, tris (dimethylaminocyclopentadienyl) hafnium ((C₅H₅)Hf[N(CH₃)₂]₃), HfCp(N(CH₃)₂)₃ and the like may be used. As the source gas, one or more of the substances exemplified above may be used.

As the source gas containing titanium (Ti) as the first element, for example, a gas containing at least one selected from the group of tetrakis (ethylmethylamino) titanium (Ti[N(CH₃)C₂H₅]₄), tetrakis (diethylamino) titanium (Ti[N(C₂H₅)₂]₄), tetrakis (dimethylamino) titanium (Ti[N(CH₃)₂]₄), Ti(O-tBu)₄, Ti(MMP)₄ and tris (dimethylaminocyclopentadienyl) titanium ((C₅H₅)Ti[N(CH₃)₂]₃), TiCp[N(CH₃)₂]₃ and the like may be used. As the source gas, one or more of the substances exemplified above may be used.

As the source gas containing silicon (Si) as the first element, for example, an aminosilane gas such as tetrakis (dimethylamino) silane (Si[N(CH₃)₂]₄, abbreviated as 4DMAS) gas, tris (dimethylamino) silane (Si[N(CH₃)₂]₃H, abbreviated as 3DMAS) gas, bis (diethylamino) silane (Si[N(C₂H₅)₂]₂H₂, abbreviated as BDEAS) gas, bis (tertiarybutylamino) silane (SiH₂[NH(C₄H₉)]₂, abbreviated as BTBAS) gas and (diisopropylamino) silane (SiH₃[N(C₃H₇)₂], abbreviated as DIPAS) gas may be used.

### <Step C: Treatment Gas Supply Step>

After the step B is completed, in the step C, for example, the treatment gas is supplied onto the wafer 200 in the process chamber 201, that is, onto the wafer 200 where the first layer containing the first element is formed on the surface thereof.

Specifically, the valve 334 is opened to supply the treatment gas into the gas supply pipe 330. After a flow rate of the treatment gas is adjusted by the MFC 332, the treatment gas whose flow rate is adjusted is supplied into the process chamber 201 through the nozzle 430, and is exhausted through the exhaust hole 204a. Thereby, the treatment gas is supplied onto the wafer 200 (treatment gas supply step). The treatment gas may be supplied in a diluted state, that is, diluted with the dilution gas such as the inert gas. In addition, in the present step, the valves 514 to 544 may be opened to supply the inert gas into the process chamber 201 through each of the nozzles 410 through 440.

By supplying the treatment gas to the wafer 200 in accordance with process conditions described below, the treatment gas reacts with the first by-product present on the wafer 200 to make it possible to remove at least a part of the first by-product.

After a supply of the treatment gas to the wafer 200 is completed (stopped), as shown in FIG. 5, preferably, the step E is performed. In the step E, with the supply of the treatment gas into the process chamber 201 stopped, the inner atmosphere of the process chamber 201 is exhausted to remove the substance such as the gas remaining in the process chamber 201 from the process chamber 201.

By performing the step E, it is possible to remove the atmosphere containing the substance remaining in the process chamber 201 (such as the treatment gas which did not react and a reaction product generated by a reaction between the treatment gas and the first by-product) from the process chamber 201.

Further, by performing the step E, it is possible to desorb the modifying agent adsorbed (physical adsorbed) on the wafer 200 after the step C from the surface of the wafer 200. As a result, it is possible to suppress a reaction between the modifying agent and the reactant supplied in a subsequent step D.

For example, the process conditions in the step C (treatment gas supply step) are as follows:
A supply flow rate of the treatment gas: from 100 sccm to 100,000 sccm, more preferably from 1,000 sccm to 10,000 sccm;
A supply time (time duration) of supplying the treatment gas: from 10 seconds to 600 seconds, more preferably from 30 seconds to 300 seconds; and
A supply flow rate of the inert gas (for each gas supply pipe): from 0 sccm to 50,000 sccm, more preferably from 5,000 sccm to 15,000 sccm.

The other process conditions of the present step may be set to be substantially the same as those of the step A of supplying the modifying agent.

The process conditions in the step E after the step C may be the same (substantially the same) as the process conditions in the step E after the step A.

As the treatment gas, for example, a gas free of oxygen (O) may be used. In addition, as the treatment gas, for example, a gas containing nitrogen (N) may be used. As the gas containing nitrogen, for example, one or more gas among ammonia (NH₃) gas, diazene (N₂H₂) gas, triazene (N₃H₃) gas and hydrazine (N₂H₄) gas may be used. Further, as the treatment gas, for example, one or more gas among hydrogen (H₂) gas, deuterium (D₂) gas, activated H₂ gas, monosilane (SiH₄) gas, disilane (Si₂H₆) gas, trisilane (Si₃H₈) gas, monoborane (BH₃) gas, diborane (B₂H₆) gas, phosphine (PH₃) gas, hydrogen chloride (HCl) gas, hydrogen fluoride (HF) gas, hydrogen bromide (HBr) gas and hydrogen iodide (HI) gas may be used. Such a gas may also be referred to as a “hydrogen-containing gas” or a “reducing gas”.

For example, it is preferable to supply the treatment gas in an absence of plasma (also referred to as “non-plasma” or “free of plasma”). By supplying the treatment gas without using the plasma, it is possible to suppress a generation of a compound in which an element contained in the treatment gas is combined with the first element in the first layer. In other words, it is possible to cause the reaction mainly involving the first by-product.

### <Step D: Reactant Supply Step>

After the step C is completed, the reactant is supplied onto the wafer 200 in the process chamber 201, that is, onto the wafer 200 where the first layer containing the first element is formed on the surface thereof.

Specifically, the valve 344 is opened to supply the reactant into the gas supply pipe 340. After a flow rate of the reactant is adjusted by the MFC 342, the reactant whose flow rate is adjusted is supplied into the process chamber 201 through the nozzle 440, and is exhausted through the exhaust hole 204a. Thereby, the reactant is supplied onto the wafer 200 (reactant supply step). The reactant may be supplied in a diluted state, that is, diluted with the dilution gas such as the inert gas. In addition, in the present step, the valves 514 to 544 may be opened to supply the inert gas into the process chamber 201 through each of the nozzles 410 to 440.

By supplying the reactant (for example, an oxidizing agent) to the wafer 200 in accordance with process conditions described below, it is possible to cause the oxidizing agent to react with the first layer. Thereby, it is possible to modify (or oxidize) the first layer into a second layer containing the first element and oxygen. In other words, it is possible to form the second layer containing the first element and oxygen and without containing nitrogen (that is, free of nitrogen).

In addition, when forming the second layer, the second by-product may be generated. The second by-product is generated by the reaction between the first by-product and the reactant. However, by performing the step C mentioned above, the amount of the first by-product is reduced. Thereby, an amount of the second by-product is also reduced.

After a process of forming the second layer on the wafer 200 is completed, the valve 344 is closed to stop a supply of the reactant into the process chamber 201.

After the supply of the reactant to the wafer 200 is completed (stopped), as shown in FIG. 5, preferably, the step E is performed. In the step E, with the supply of the reactant into the process chamber 201 stopped, the inner atmosphere of the process chamber 201 is exhausted to remove the substance such as the gas remaining in the process chamber 201 from the process chamber 201.

By performing the step E, it is possible to remove the atmosphere containing the substance remaining in the process chamber 201 (such as the reactant which did not react or which did contribute to a formation of the second layer, and the second by-product) from the process chamber 201.

In addition, by performing the step E, it is possible to desorb the modifying agent contained in the adsorption layer (that is, the modifying agent physically adsorbed to the surface of the wafer 200) from the surface of the wafer 200. As a result, it is possible to prevent (suppress) the modifying agent from remaining in the film formed on the wafer 200. Thereby, it is possible to form the film whose concentration of the impurities caused by the modifying agent is low.

Further, by performing the step E, it is possible to remove the first by-product and the second by-product (which are adhered to the adsorption layer) from the surface of the wafer 200 together with the modifying agent contained in the adsorption layer (that is, the modifying agent physically adsorbed to the surface of the wafer 200). As a result, it is possible to prevent (suppress) the first by-product and the second by-product from remaining in the film formed on the wafer 200. Further, it is also possible to form the film whose step coverage and/or thickness uniformity is desirable within the surface of the wafer 200 and whose concentration of the impurities caused by the first by-product and the second by-product is low.

By performing the step E in accordance with one of the examples described above, it is possible to more efficiently remove a part of the modifying agent physically adsorbed on the surface of the wafer 200 from the surface of the wafer 200, and it is also possible to more reliably obtain the effects described above.

For example, the process conditions in the step D (reactant supply step) are as follows:
A supply flow rate of the reactant: from 100 sccm to 100,000 sccm, more preferably from 1,000 sccm to 10,000 sccm;
A supply time (time duration) of supplying the reactant: from 10 seconds to 600 seconds, more preferably from 30 seconds to 300 seconds; and
A supply flow rate of the inert gas (for each gas supply pipe): from 0 sccm to 50,000 sccm, more preferably from 5,000 sccm to 15,000 sccm.

The other process conditions of the present step may be set to be substantially the same as those of the step A of supplying the modifying agent.

The process conditions in the step E may be the same (substantially the same) as the process conditions in the step E after the step A.

As the reactant gas, the oxidizing agent (oxidizing gas) (that is, a gas containing oxygen) may be used. As the oxidizing agent, for example, a gas containing oxygen and hydrogen may be used. As the gas containing oxygen and hydrogen, for example, a gas such as water vapor (H₂O gas), hydrogen peroxide (H₂O₂) gas, a gaseous mixture of hydrogen (H₂) gas and oxygen (O₂) gas and a gaseous mixture of the H₂ gas and ozone (O₃) gas may be used. In addition to or instead of the gas containing oxygen and hydrogen, the oxygen-containing gas may be used as the oxidizing agent. As the oxygen-containing gas, for example, a gas such as the O₂ gas, activated O₂ gas, the O₃ gas, nitrous oxide (N₂O) gas, nitric oxide (NO) gas, nitrogen dioxide (NO₂) gas, carbon monoxide (CO) gas and carbon dioxide (CO₂) gas may be used. The gas containing oxygen and hydrogen is also a type of the oxygen-containing gas. As the oxidizing agent, one or more of the substances exemplified above may be used.

Further, in the present specification, the description of two gases such as “a gaseous mixture of hydrogen (H₂) gas and oxygen (O₂) gas” refers to a mixed gas of the two gases such as the H₂ gas and the O₂ gas. When the mixed gas of the two gases is supplied, the two gases may be mixed (pre-mixed) in a supply pipe and then supplied into the process chamber 201. Alternatively, the two gases may be separately supplied into the process chamber 201 through different supply pipes, and then the two gases separately supplied into the process chamber 201 may be mixed (post-mixed) in the process chamber 201.

### <Performing First Cycle Predetermined Number of Times (X Times)>

For example, by performing a first cycle including the above-mentioned steps B and C a predetermined number of times (X times, where X is an integer of 1 or 2 or more), it is possible to form the first layer containing the first element on the wafer 200, that is, on the surface of the wafer 200 including the inner surface of the concave structure formed on the surface of the wafer 200. It is preferable that the first cycle mentioned above is repeatedly performed a plurality number of times.

### <Performing Second Cycle Predetermined Number of Times (Y Times)>

For example, by performing a second cycle including the above-mentioned steps A to E a predetermined number of times (Y times, where Y is an integer of 1 or 2 or more), it is possible to form the film containing the first element (for example, an oxide film containing the first element) on the wafer 200, that is, on the surface of the wafer 200 including the inner surface of the concave structure formed on the surface of the wafer 200. It is preferable that the second cycle mentioned above is repeatedly performed a plurality number of times. That is, it is preferable that the second cycle is repeatedly performed the plurality number of times until a thickness of a stacked film (that is, the oxide film containing the first element) reaches a desired thickness while a thickness of the second layer formed per each cycle is smaller than the desired thickness.

### <Performing Third Cycle Predetermined Number of Times (Z Times)>

For example, by performing a third cycle including the above-mentioned steps A, B and C a predetermined number of times (Z times, where Z is an integer of 1 or 2 or more), it is possible to form the first layer containing the first element on the wafer 200, that is, on the surface of the wafer 200 including the inner surface of the concave structure formed on the surface of the wafer 200. It is preferable that the third cycle mentioned above is repeatedly performed a plurality number of times.

### <After-purge Step and Returning to Atmospheric Pressure Step>

After a process of forming the film on the wafer 200 is completed, the inert gas serving as the purge gas is supplied into the process chamber 201 through each of the nozzles 410 to 440, and then is exhausted through the exhaust hole 204a. Thereby, the inner atmosphere of the process chamber 201 is purged with the purge gas. As a result, the substance such as the gas remaining in the process chamber 201 and the reaction by-product remaining in the process chamber 201 are removed from the process chamber 201 (after-purge step). Thereafter, the inner atmosphere of the process chamber 201 is replaced with the inert gas (substitution by inert gas), and the inner pressure of the process chamber 201 is returned to the normal pressure (atmospheric pressure) (returning to atmospheric pressure step).

### <Boat Unloading Step and Wafer Discharging Step>

Thereafter, the seal cap 219 is lowered by the boat elevator 115 and the lower end of the outer tube 203 is opened. The boat 217 with the wafers 200 (which are processed) charged therein is unloaded out of the outer tube 203 through the lower end of the outer tube 203 (boat unloading step). Then, the wafers 200 (which are processed) are discharged (transferred) out of the boat 217 (wafer discharging step).

(3) Effects according to Present Embodiments

According to the present embodiments, it is possible to obtain one or more of the following effects.

(a) By performing the step C on the wafer 200 on which the step B has been performed, it is possible to reduce the amount of the first by-product present on the wafer 200. Thereby, it is possible to reduce the amount of the second by-product generated by the reaction between the first by-product and the reactant. As a result, it is possible to suppress an occurrence of an unintended reaction between the second by-product present on the wafer 200 and the source gas to be supplied thereafter. That is, it is possible to improve the thickness uniformity of the film within the surface of the wafer 200. When the concave structure is formed on the surface of the wafer 200, it is possible to improve the step coverage of the film formed in the concave structure.

(b) By performing the step C on the wafer 200 on which the step B has been performed, it is possible to reduce an amount of the modifying agent (adsorption layer) present on the wafer 200. By reducing the amount of the adsorption layer, it is possible to suppress the reaction between the adsorption layer and the reactant supplied in the step D. When a material containing at least one selected from the group of the hydrocarbon group, the amino group and the alkylamino group is used as the modifying agent and the oxygen-containing gas is used as the reactant, the second by-product (such as the H₂O and the OH-group) may be generated. However, even in such a case, by performing the step C, it is possible to reduce the adsorption layer. Thereby, it is possible to suppress the reaction between the adsorption layer and the reactant.

(c) By performing the step C on the wafer 200 on which the steps A and B have been performed, in addition to at least one among the effects (a) and (b) mentioned above, it is possible to reduce the amount of the second by-product generated by the reaction between the adsorption layer formed on the wafer 200 in the step A and the reactant. As a result, it is possible to suppress the occurrence of the unintended reaction between the second by-product present on the wafer 200 and the modifying agent to be supplied thereafter. In the film forming process in which the step A is performed, the second by-product (at least one selected from the group of the H₂O, the OH-group and the like) may react with the modifying agent and as a result, an original effect of the modifying agent may be reduced. However, by performing the step C, it is possible to obtain the effect of the modifying agent.

(d) By performing the step B and the step C X times (preferably, X is an integer of 2 or more) (that is, by performing the first cycle X times), it is possible to remove the ligand (particularly, the organic ligand) bonded to the first element adsorbed to the wafer 200. The ligand bonded to the first element adsorbed to the wafer 200 acts as a steric hindrance. Thus, the first element cannot be adsorbed to sites on the wafer 200 where the first element may be adsorbed. By performing the step B and the step C X times, it is possible to reduce the steric hindrance, and it is also possible to promote the adsorption of the first element to the wafer 200.

(e) By performing the steps A to C Z times (preferably, Z is an integer of 2 or more), it is possible to obtain the effect of (d) for a region of the wafer 200 to which the modifying agent is difficult to adsorb. In the present specification, for example, the “region of the wafer 200 to which the modifying agent is difficult to adsorb” may indicate a bottom portion of the concave structure formed in the wafer 200.

(f) For example, when the source gas containing a methylamino group (N(CH₃)ₐ group, where a is an integer of 1 or more) is used as the ligand of the source gas and the NH₃ gas is used as the treatment gas, the ligand can be decomposed by the following reaction. A decomposition product generated by such a decomposition can be exhausted from the process chamber 201.

(N(CH₃)ₐ)+bNH₃→CN₂+dC₂H₆+eCH₃+fCH₄+gH₂

where a to g are integers of 0 or more. In addition, although the present embodiments are described by way of an example in which the methylamino group and the NH₃ gas are used, the present embodiments are not limited thereto. That is, similar reactions may occur when using other substances of the embodiments of the present disclosure.

### (4) Other Embodiments of Present Disclosure

While the technique of the present disclosure is described in detail by way of the embodiments mentioned above, the technique of the present disclosure is not limited thereto. The technique of the present disclosure may be modified in various ways without departing from the scope thereof.

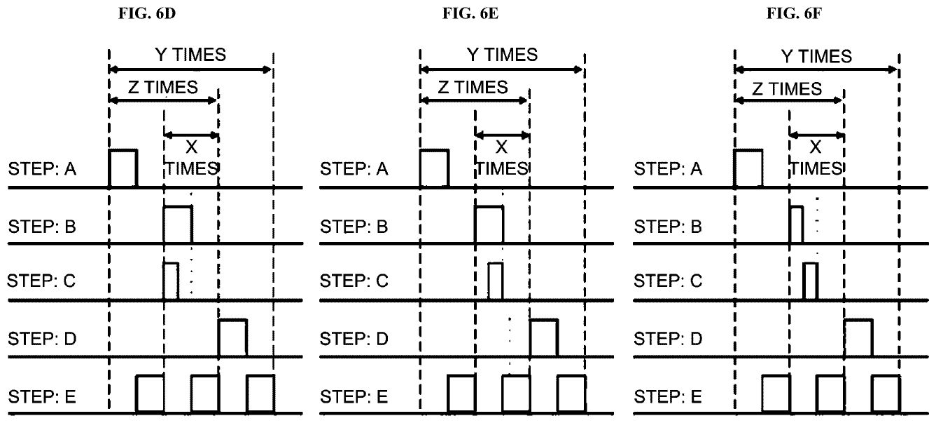

For example, FIGS. 6A to 6F are diagrams schematically illustrating modified examples of the process sequence (substrate processing sequence) according to the embodiments of the present disclosure, respectively. In FIG. 5, a pattern in which “the step B→the step E→the step C are performed” is shown as the process sequence. However, according to the modified examples, patterns in which the step E is not performed between the step B and the step C are shown. In some of the modified examples, the step B and the step C may be performed partially in parallel. In FIG. 6A, the pattern in which the step C is performed during the step B is shown. In other words, FIG. 6A shows the pattern in which the step C is started after the step B is started and the step B is completed (ended) after the step C is completed. FIG. 6B shows the pattern in which the step B is performed during the step C. In other words, FIG. 6B shows the pattern in which the step B is started after the step C is started and the step C is completed after the step B is completed. FIG. 6C shows the pattern in which the step C is started during the step B and the step C is completed after the step B is completed. FIG. 6D shows the pattern in which the step B and the step C are started simultaneously and the step B is completed after the step C is completed. FIG. 6E shows the pattern in which the step C is started after the step B is started and the step B and the step C are completed simultaneously. FIG. 6F shows the pattern in which the step C is performed after the step B without performing the step E therebetween. According to the modified examples mentioned above, it is possible to obtain substantially the same effects as in the embodiments mentioned above. In addition, in the modified examples, by performing the steps B and C in the process chamber 201 such that at least a part of the source gas and the treatment gas are mixed, as in the patterns mentioned above, it is possible to adsorb the first element contained in the source gas to the wafer 200 while removing the ligand contained in the source gas with the treatment gas in a gaseous phase. In addition, since the ligand contained in the source gas can be removed in the gas phase, even when the second by-product is present on the wafer 200, it is possible to suppress a gaseous phase reaction (CVD reaction) between the second by-product and the source gas. In addition, since the step E is not performed between the step B and the step C, it is possible to shorten the time of the film forming process. In other words, it is possible to improve a manufacturing throughput of the semiconductor device.

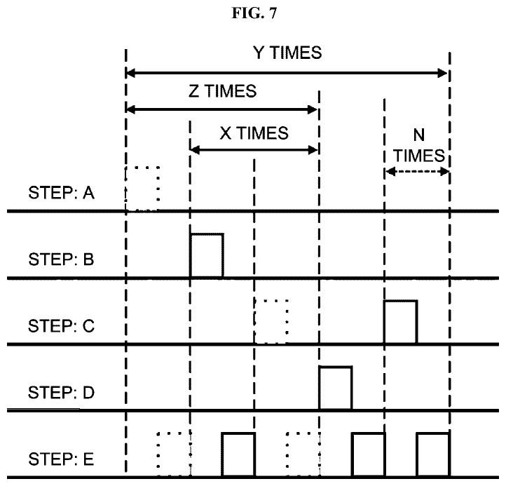

For example, a process sequence (substrate processing sequence) shown in FIG. 7 may be used. FIG. 7 shows a pattern in which the step C is performed after the step D in the process sequence shown in FIG. 5. In such a sequence, as shown by a dashed box in FIG. 7, the step A and the step C (which is between the step B and the step D) may not be performed. According to the present modified example, it is possible to obtain substantially the same effects as in the embodiments mentioned above. According to the present modified example, in the step D, the second by-product (such as the H₂O and the OH-group) is generated, and the wafer 200 is in a state in which the second by-product is adsorbed thereto. By supplying the treatment gas of the step C to the wafer 200 in such a state, it is possible to remove the second by-product. As a result, it is possible to suppress the reaction between the second by-products and the source gas. When the modifying agent is used, it is also possible to suppress the reaction between the second by-product and the modifying agent. In addition, by performing the step C (that is, a step of supplying the hydrogen-containing gas) after the step D, it is possible to convert an OH-terminated surface of the wafer 200 to a hydrogen-terminated surface. Further, in the step C, when the NH₃ gas is supplied, it is possible to replace an OH-termination with an NH-termination. As a result, it is possible to reduce the second by-product exposed on the surface of the wafer 200, and it is also possible to reduce at least one among the reaction between the second by-product and the source gas and the reaction between the second by-product and the modifying agent. Further, in the step C after the step D, a hydrogen-termination and the NH-termination are formed on the OH-termination on the wafer 200 or on the H₂O adsorbed on the wafer 200, and it is considered that the OH- and the H₂O exposed on the surface of the wafer 200 are reduced. That is, the molecule of the treatment gas supplied in the step C and a part of the molecule of the treatment gas cover at least a part of the second by-product present on the surface of the wafer 200.

For example, as shown in FIG. 7, the step C after the step D may be performed N times (N is an integer of 1 or more). By performing the step C after the step D a plurality of times, it is possible to reduce the amount of the second by-product present on the wafer 200. Such a process is preferably performed when the concave structure is formed on the wafer 200. To uniformly form the film in the concave structure, it is preferable to form the adsorption layer by the modifying agent more on an upper portion of the concave structure than on the bottom portion. However, when the second by-product is also present on the bottom portion of the concave structure, the second by-product present on the bottom portion of the concave structure and the modifying agent may easily react with each other (that is, the modifying agent is easily adsorbed to the second by-product). In such a state, the modifying agent may be adsorbed on the bottom portion of the concave structure, and the adsorption layer may also be formed on the bottom portion of the concave structure. As a result, it may be difficult to obtain the effect of improving the step coverage by the adsorption layer. To address such a problem, by performing the step C after the step D N times as shown in FIG. 7, it is possible to remove the second by-product present on the bottom portion of the concave structure.

In addition, in other words, the step C after the step D shown in FIG. 7 may also be referred to as the step C before the step B. That is, the step C after the step D may mean that the treatment gas is supplied before the supply of the source gas. By supplying the treatment gas before the supply of the source gas, it is possible to modify the surface of the wafer 200 to a state in which the source gas is difficult to be adsorbed. That is, it is possible to obtain an effect of inhibiting the source gas from adsorbing to the wafer 200 by supplying the treatment gas as described above. For example, by using the NH₃ gas as the treatment gas, it is possible to terminate the surface of the wafer 200 with an NH-group. At least one among the hydrocarbon group, the amino group and the alkylamino group contained in the source gas may be characterized in that it is difficult for them to be bonded (adsorbed) to the NH-group. Thereby, it is possible to suppress the source gas from adsorbing to the wafer 200. When the concave structure is formed on the surface of the wafer 200, it is possible to suppress the adsorption of the source gas to the upper portion of the concave structure by forming an NH-group termination at the upper portion of the concave structure. As a result, it is possible to improve the uniformity (step coverage) of the film formed in the concave structure.

For example, the embodiments mentioned above are described by way of an example in which the step A is performed. However, the technique of the present disclosure is not limited thereto. For example, as shown by the dashed boxes in FIG. 5, the step A may be omitted, and the step E may also be omitted after performing the step A. Even when the step A is not performed, the amount of the first by-product caused by the source gas supplied to the wafer 200 in the step B can be reduced in the step C.

For example, the embodiments mentioned above are described by way of an example in which a batch type vertical substrate processing apparatus capable of simultaneously processing a plurality of substrates is used to form the film. However, the technique of the present disclosure is not limited thereto. For example, the technique of the present disclosure may also be preferably applied when a single wafer type substrate processing apparatus capable of processing one or several substrates at a time is used to form the film. For example, the embodiments mentioned above are described by way of an example in which a substrate processing apparatus including a hot wall type process furnace is used to form the film. However, the technique of the present disclosure is not limited thereto. For example, the technique of the present disclosure may also be preferably applied when a substrate processing apparatus including a cold wall type process furnace is used to form the film.

The process procedures and the process conditions of each process using the substrate processing apparatuses exemplified above may be substantially the same as those of the embodiments or the modified examples mentioned above. Even in such a case, it is possible to obtain substantially the same effects as in the embodiments or the modified examples mentioned above.

For example, the embodiments mentioned above are described by way of an example in which the process sequence mentioned above is performed in the same process chamber of the same substrate processing apparatus (that is, in-situ). However, the technique of the present disclosure is not limited thereto. For example, a step in the process sequence mentioned above and another step in the process sequence mentioned above may be performed in different process chambers of different substrate processing apparatuses (that is, ex-situ), or may be performed in different process chambers of the same substrate processing apparatus.

It is preferable that the process recipe (that is, a program defining parameters such as process procedures and process conditions of the substrate processing) used to form each type of film is prepared individually in accordance with the contents of the substrate processing such as a type of the film to be formed, a composition ratio of the film, a quality of the film, a thickness of the film, the process procedures and the process conditions of the substrate processing. That is, a plurality of process recipes are prepared in advance. Then, when starting the substrate processing, an appropriate process recipe is preferably selected among the process recipes in accordance with the contents of the substrate processing. Specifically, it is preferable that the process recipes are stored (installed) in the memory 121c of the substrate processing apparatus 10 in advance via an electric communication line or the recording medium (for example, the external memory 123) storing the process recipes prepared individually in accordance with the contents of the substrate processing. Then, when starting the substrate processing, the CPU 121a preferably selects the appropriate process recipe among the process recipes stored in the memory 121c of the substrate processing apparatus 10 in accordance with the contents of the substrate processing. With such a configuration, various films of different types, different composition ratios, different qualities and different thicknesses may be universally formed with a high reproducibility using a single substrate processing apparatus. In addition, since a burden on an operator such as inputting the process procedures and the process conditions may be reduced, various processes (that is, the substrate processing) can be performed quickly while avoiding a misoperation of the apparatus.

Further, the technique of the present disclosure may be implemented by changing an existing process recipe stored in the substrate processing apparatus 10 to a new process recipe. When changing the existing process recipe to the new process recipe, the new process recipe according to the technique of the present disclosure may be installed in the substrate processing apparatus 10 via the electric communication line or the recording medium storing the process recipes. Alternatively, the existing process recipe already stored in the substrate processing apparatus 10 may be directly changed to the new process recipe according to the technique of the present disclosure by operating the input/output device 122 of the substrate processing apparatus 10.

Further, for example, the technique of the present disclosure may be used in a structure such as a word line of a DRAM and a NAND flash memory of a three-dimensional structure.

For example, the embodiments and the modified examples mentioned above may be appropriately combined. The process procedures and the process conditions of each combination thereof may be substantially the same as those of the embodiments mentioned above.

As described above, according to some embodiments of the present disclosure, it is possible to improve the quality of the film formed on the substrate.

What is claimed is:

1. A substrate processing method comprising:
forming a film containing a first element on a substrate by performing a cycle a predetermined number of times, wherein the cycle comprises:
(a) supplying a source gas containing the first element and an organic ligand to the substrate;
(b) supplying a treatment gas to the substrate to reduce an amount of by-products present on a surface of the substrate; and
(c) supplying a first reactive gas to the substrate.

2. The substrate processing method of claim 1, wherein the organic ligand contains at least one of a hydrocarbon group or an amino group.

3. The substrate processing method of claim 1, wherein the organic ligand contains a hydrocarbon group and an amino group.

4. The substrate processing method of claim 1, wherein the organic ligand contains an alkylamino group.

5. The substrate processing method of claim 1, wherein the first reactive gas is a gas containing oxygen, and a second reactive gas that is free of oxygen is supplied in (b).

6. The substrate processing method of claim 5, wherein the second reactive gas is a reducing gas.

7. The substrate processing method of claim 5, wherein the first reactive gas contains at least one selected from the group of O₂, O₃, H₂O, H₂O₂ and activated O₂, and the second reactive gas contains at least one selected from the group of NH₃, N₂H₄, H₂, activated H₂, D₂, SiH₄, Si₂H₆, Si₃H₈, BH₃, B₂H₆ and PH₃.

8. The substrate processing method of claim 5, wherein the second reactive gas is a gas containing nitrogen, and a film containing the first element and oxygen and free of nitrogen is formed on the substrate in (c).

9. The substrate processing method of claim 5, wherein (b) is performed in a non-plasma state.

10. The substrate processing method of claim 1, wherein, in the cycle, (c) is performed after (a) and (b) are performed a predetermined number of times.

11. The substrate processing method of claim 1, wherein, in the cycle, (b) is performed after (c).

12. The substrate processing method of claim 10, wherein, in the cycle, (b) is performed after (c).

13. The substrate processing method of claim 1, wherein (a) and (b) are performed partially in parallel.

14. The substrate processing method of claim 1, wherein, in (b), the organic ligand present on the substrate is decomposed.

15. A method of manufacturing a semiconductor device, comprising:
the substrate processing method of claim 1.

16. A non-transitory computer-readable recording medium storing a program that causes a substrate processing apparatus, by a computer, to perform:
forming a film containing a first element on a substrate by performing a cycle a predetermined number of times, wherein the cycle comprises:
(a) supplying a source gas containing the first element and an organic ligand to the substrate;
(b) supplying a treatment gas to the substrate to reduce an amount of by-products present on a surface of the substrate; and
(c) supplying a first reactive gas to the substrate.

17. A substrate processing apparatus comprising:
a source gas supplier configured to supply a source gas containing a first element and an organic ligand to a substrate;
a treatment gas supplier configured to supply a treatment gas to the substrate;
a first reactive gas supplier configured to supply a first reactive gas to the substrate; and
a controller configure to be capable of controlling the source gas supplier, the treatment gas supplier and the first reactive gas supplier to form a film containing the first element on the substrate by performing a cycle a predetermined number of times,
wherein the cycle comprises:
(a) supplying the source gas to the substrate;
(b) supplying the treatment gas to the substrate to reduce an amount of by-products present on a surface of the substrate; and
(c) supplying the first reactive gas to the substrate.
